(19) United States
(12) Patent Application Publication
(10) Pub. No.: US 2026/0247848 A1
(43) Pub. Date: Aug. 20, 2026

(54) METHOD OF MANUFACTURING MICROSTRUCTURE ARRAY AND MICRO LIGHT-EMITTING DIODE AND METHOD OF MANUFACTURING THE SAME AND DISPLAY DEVICE

(71) Applicant: UIF (University Industry Foundation), Yonsei University, Seoul (KR)

(72) Inventors: Wooyoung SHIM, Seoul (KR); Jae-Min MYOUNG, Goyang-si (KR); JiHun YEOM, Seoul (KR); Min Seong KIM, Gwangmyeong-si (KR); Jae Youn JEONG, Seoul (KR)

(21) Appl. No.: 19/457,437

(22) Filed: Jan. 23, 2026

(30) Foreign Application Priority Data
Feb. 20, 2025 (KR) 10-2025-0022561

(51) Int. Cl. H10H 20/819; H10K 30/50

(52) U.S. Cl. CPC H10K 71/12; H10K 71/20; H10K 71/40; H10K 71/60; H10K 85/50

(57) ABSTRACT

Disclosed are a method of manufacturing a microstructure array, a micro light-emitting diode, and a method of manufacturing the same and a display device, the method of manufacturing a microstructure array including: preparing a tip array including a plurality of tips, each of the plurality of tips having a truncated pyramidal shape, applying a perovskite precursor solution on the tip array, annealing the perovskite precursor solution applied on the tip array to form a plurality of perovskite crystal patterns including perovskite nanocrystals formed from the perovskite precursor solution on the tip array, and transferring the plurality of perovskite crystal patterns onto a substrate to form a plurality of microstructures.

### CROSS-REFERENCE TO RELATED APPLICATION

This application claims priority to and the benefit of Korean Patent Application No. 10-2025-0022561 filed with the Korean Intellectual Property Office on Feb. 20, 2025, the entire contents of which are incorporated herein by reference.

### BACKGROUND

### 1. Field

The present disclosure relates to a method of manufacturing a microstructure array, a micro light-emitting diode, a method of manufacturing the micro light-emitting diode, and a display device.

### 2. Description of the Related Art

In line with the recent trend toward lighter and thinner display devices, research is being conducted on light emitting devices that use self-luminous light emitters, such as organic light-emitting diodes or quantum dot light-emitting diodes.

Perovskite is one of the self-luminous light emitters, and is attracting attention as a key material for next-generation light emitting devices based on its high color purity and excellent luminescence characteristics.

### SUMMARY

However, perovskite may be required a complex synthesis process for crystallization and may be vulnerable to chemical solutions, making it difficult to implement micro-scale patterns without performance degradation.

An embodiment provides a method of manufacturing a microstructure array including perovskite light emitters capable of simplifying the process without performance degradation.

Another embodiment provides a method of manufacturing a micro light-emitting diode including the microstructure array.

Another embodiment provides a micro light-emitting diode manufactured by the method.

Another embodiment provides a display device including the micro light-emitting diode.

According to an embodiment, a method of manufacturing a microstructure array includes preparing a tip array including a plurality of tips, each of the plurality of tips having a truncated pyramidal shape, applying a perovskite precursor solution on the tip array, annealing the perovskite precursor solution applied on the tip array to form a plurality of perovskite crystal patterns including perovskite nanocrystals formed from the perovskite precursor solution on the tip array, and transferring the plurality of perovskite crystal patterns onto a substrate to form a plurality of microstructures.

The preparing of the tip array may include preparing a mold having a plurality of recesses, each of the plurality of recesses having a truncated pyramidal shape, supplying an elastic polymer solution including an elastic polymer precursor and a curing agent in a weight ratio of about 5:1 to about 20:1 to the mold, curing the elastic polymer solution to cast it into the tip array including the plurality of tips, and separating the tip array from the mold.

The elastic polymer precursor may include a polydimethylsiloxane precursor.

The preparing of the tip array may further include performing a Soxhlet extraction.

A surface roughness of an upper surface of the tip may be about 1 nm to about 5 nm.

A width of an upper surface of the tip may be less than about 50 μm.

The method may further include performing oxygen plasma treatment on the surfaces of the plurality of tips before applying the perovskite precursor solution onto the tip array.

A contact angle of the surface of the plurality of tips treated with the oxygen plasma may be from 0 degrees to about 20 degrees.

The annealing may be performed at a temperature of about 50 to about 200° C.

An average crystal size of the perovskite nanocrystals in each of the perovskite crystal patterns may be less than about 100 nm.

The method may further include forming an electrode or a stack of an electrode and a charge auxiliary layer on the substrate before transferring of the plurality of perovskite crystal patterns, and the perovskite crystal patterns may be transferred onto the electrode or the stack of the electrode and the charge auxiliary layer.

Each of the microstructures may be configured to emit light in at least one wavelength region among red wavelength region, green wavelength region, and blue wavelength region.

According to another embodiment, a method of manufacturing a micro light-emitting diode includes: forming a first electrode on a substrate, forming a microstructure array on the first electrode, and forming a second electrode on the microstructure array, wherein the forming of the microstructure array includes: forming a first microstructure array in which a plurality of first microstructures are arranged, each of the plurality of first microstructures including first perovskite nanocrystals emitting light of a first wavelength region; forming a second microstructure array in which a plurality of second microstructures are arranged, each of the plurality of second microstructures including second perovskite nanocrystals emitting light of a second wavelength region different from the first wavelength region; and forming a third microstructure array in which a plurality of third microstructures are arranged, each of the plurality of third microstructures including third perovskite nanocrystals emitting light of a third wavelength region different from the first and second wavelength regions, wherein at least one of the forming of the first, second, and third microstructure arrays may be performed by the method.

According to another embodiment, a micro light-emitting diode manufactured by the method is provided.

According to another embodiment, a display device including the micro light-emitting diode is provided.

Perovskite synthesis and micro-scale patterning may be implemented in a single process without chemical solutions, simplifying the process and effectively reducing or preventing performance degradation.

### BRIEF DESCRIPTION OF THE DRAWINGS

FIG. 1 is a plan view showing an example of a tip array used in the manufacture of a microstructure array according to an embodiment,

FIG. 2 is a cross-sectional view showing an example of a tip of the tip array of FIG. 1,

FIG. 3 is a cross-sectional view showing an example of a mold used in the manufacture of the tip array of FIG. 1,

FIGS. 4 to 11 are schematic views sequentially showing examples of a method of manufacturing a microstructure array according to embodiments,

FIGS. 12A, 12B, 12C, 13A, 13B, 13C, and 14 to 17 are schematic views showing another example of a method of manufacturing a microstructure array according to embodiments,

FIG. 18 is a schematic view showing an example of an arrangement of sub-pixels of a micro light-emitting diode according to an embodiment,

FIG. 19 is a schematic view showing a micro light-emitting diode according to an embodiment,

FIG. 20 is a cross-sectional view showing one sub-pixel of the micro light-emitting diode of FIG. 19,

FIG. 21 is a photoluminescence photograph of a green light emitting micro light-emitting diode according to Example 5,

FIG. 22 is a photoluminescence photograph of a micro red light-emitting diode according to Example 6,

FIG. 23 is a photoluminescence photograph of a blue light emitting micro light-emitting diode according to Example 7, and

FIG. 24 is a photoluminescence photograph of a multi-color light emitting micro light-emitting diode according to Example 8.

### DETAILED DESCRIPTION

Hereinafter, specific embodiments will be described in detail so that those of ordinary skill in the art can easily implement them. However, this disclosure may be embodied in many different forms and is not construed as limited to the example embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present.

Hereinafter, the term ‘combination’ includes s mixture and a stacked structure of two or more.

Hereinafter, the dimension may be a width, a length and/or a thickness, and the width and length may be sizes extending in different directions (e.g., vertically) within the same plane, and the thickness may be a size extending in a direction perpendicular to the width and length, respectively. For example, in the case of a structure formed on a substrate, the sizes extending in the in-plane direction of the substrate (x and y directions) may be the width and length, respectively, and the size extending in the thickness direction of the substrate (z direction) may be the thickness. If the shape of the plane is a circular or elliptical shape, the width may be a diameter or a long diameter.

Hereinafter, a ‘precursor’ may be a reactant or a previous material used to obtain a final product, and may include a monomer, an oligomer, and/or a pre-polymer.

An example of a method of manufacturing a microstructure array according to an embodiment is described with reference to the drawings.

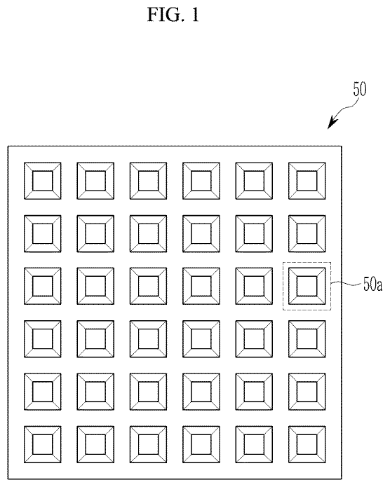

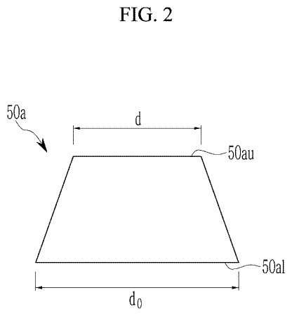

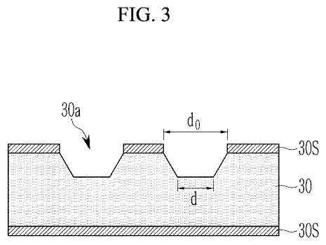

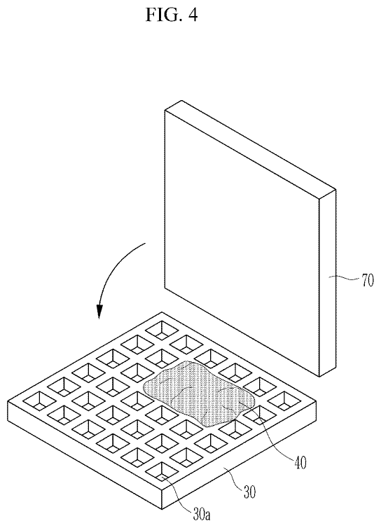

FIG. 1 is a plan view showing an example of a tip array used in the manufacture of a microstructure array according to an embodiment, FIG. 2 is a cross-sectional view showing an example of a tip of the tip array of FIG. 1, FIG. 3 is a cross-sectional view showing an example of a mold used in the manufacture of the tip array of FIG. 1, and FIGS. 4 to 11 are schematic views sequentially showing examples of a method of manufacturing a microstructure array according to embodiments.

A method of manufacturing a microstructure array 120 according to an embodiment may include: preparing a blunt tip array 50 including a plurality of blunt tips 50a, each of the plurality of blunt tips 50a having a truncated pyramidal shape; applying a perovskite precursor solution 80 on the blunt tip array 50; annealing the perovskite precursor solution applied on the tip array to form a plurality of perovskite crystal patterns 120a including perovskite nanocrystals formed from the perovskite precursor solution 80 on the blunt tip array 50; and transferring the plurality of perovskite crystal patterns 120a onto a substrate 310 to form a microstructure array 120 including a plurality of microstructures 120a.

First, referring to FIG. 1, a blunt tip array 50 (hereinafter, referred to as “tip array”) for forming a microstructure array 120 is prepared. The tip array 50 may be a polymer pen array formed by polymer pen lithography PPL.

The tip array 50 includes a plurality of blunt tips 50a (hereinafter, referred to as “tips”) arranged along rows and/or columns or randomly, and each tip 50a may be a support on which a synthesis of the perovskite nanocrystals and a formation of a perovskite crystal pattern 120a including perovskite nanocrystals are performed, as described later.

Referring to FIG. 2, each tip 50a may have an upper surface 50au that is not sharp at the end and is substantially parallel to the lower surface 50al, and the width may change from the lower surface 50al to the upper surface 50au so that the tip 50a may have a truncated pyramidal shape with the upper surface 50au being substantially flat. The planar shape of the upper surface 50au of the tip 50a may be a polygon such as a square, rectangle, hexagon or octagon, a circular or elliptical shape depending on the microstructure 120a to be formed, but is not limited thereto.

The width, length or diameter d of the upper surface 50au of the tip 50a may be smaller than the width, length or diameter do of the lower surface 50al of the tip 50a, and the width, length or diameter d of the upper surface 50au of the tip 50a may be determined according to the width, length or diameter of the perovskite crystal pattern 120a to be formed.

For example, at least one of the width and length (e.g., each of the width and the length) or the diameter d of the tip 50a may be less than about 50 μm, and within the above range may be less than or equal to about 45 μm, less than or equal to about 40 μm, less than or equal to about 35 μm, less than or equal to about 30 μm, less than or equal to about 25 μm, less than or equal to about 20 μm, less than or equal to about 15 μm, less than or equal to about 10 μm, less than or equal to about 9 μm, or less than or equal to about 8 μm, within the above range, greater than or equal to about 0.01 μm and less than about 50 μm, about 0.01 μm to about 45 μm, about 0.01 μm to about 40 μm, about 0.01 μm to about 35 μm, about 0.01 μm to about 30 μm, about 0.01 μm to about 25 μm, about 0.01 μm to about 20 μm, about 0.01 μm to about 15 μm, about 0.01 μm to about 10 μm, about 0.01 μm to about 9 μm, about 0.01 μm to about 8 μm, greater than or equal to about 0.1 μm and less than about 50 μm, about 0.1 μm to about 45 μm, about 0.1 μm to about 40 μm, about 0.1 μm to about 35 μm, about 0.1 μm to about 30 μm, about 0.1 μm to about 25 μm, about 0.1 μm to about 20 μm, about 0.1 μm to about 15 μm, about 0.1 μm to about 10 μm, about 0.1 μm to about 9 μm, or about 0.1 μm to about 8 μm.

The tip array 50 including the plurality of tips 50a may be manufactured using a mold 30.

Referring to FIG. 3, the mold 30 may be, for example, a Si mold, and the upper and lower parts of the mold 30 may each be covered with a silicon oxide film 30S. The mold 30 may be transparent. The mold 30 may have a plurality of recesses 30a arranged along rows and/or columns, and each of recesses 30a may be a region to be filled with an elastic polymer solution 40 and to be cast into the tip 50a, as described later.

The plurality of recesses 30a in the mold 30 may be formed, for example, by photolithography and etching (e.g., wet etching), and the shape and size of the recess 30a may be controlled by adjusting the etching rate and etching time, etc.

For example, the plurality of recesses 30a in the mold 30 may be formed in the following manner. First, photoresist (not shown) is applied on a mold 30 covered with a silicon oxide film 30S, and photoresist patterns with a plurality of holes are formed through lithography. Next, the remaining photoresist in the plurality of holes is removed, for example, using oxygen plasma (O₂ plasma), and the mold 30 is immersed in an etchant for an oxide to etch the silicon oxide film 30S exposed through the holes. At this time, the etching time may vary depending on the thickness of the silicon oxide film 30S, and for example, when the thickness of the silicon oxide film 30S may be about 1000 Å to about 5000 Å, the etching may be performed for about 30 seconds to about 10 minutes. Next, the mold 30 is immersed in another etching solution (e.g., a basic aqueous solution such as a KOH aqueous solution at about 70° C. to about 110° C.) for about 1 minute to about 10 minutes to etch the exposed mold 30. The shape of the recess 30a may be controlled depending on the etching rate, for example, the etching rate in the (100) plane direction may be about 0.1 to about 0.6 μm/min, and within the above range, may be about 0.2 to about 0.5 μm/min or about 0.3 to about 0.4 μm/min. By performing the etching with the above-mentioned etching rate, a plurality of the truncated pyramidal shaped recesses 30a may be efficiently formed.

The shape and the size of the recess 30a may be substantially the same as the shape and size of the tip 50a to be formed, and may have a truncated pyramidal shape in which the width, length or diameter d of the lower surface of the recess 30a is smaller than the width, length or diameter do of the inlet. The width, length or diameter d of the lower surface of the recess 30a may be substantially equal to the width, length or diameter d of the upper surface 50au of the tip 50a described above, and the width, length or diameter do of the surface of the recess 30a may be substantially equal to the width, length or diameter do of the lower surface 50al of the tip 50a described above.

Referring to FIG. 4, an elastic polymer solution 40 is supplied on the mold 30. The elastic polymer solution 40 may include an elastic polymer precursor and a curing agent. The elastic polymer solution may include an elastic silicon containing precursor such as a polydimethylsiloxane (PDMS) precursor, a polyurethane, a silicone rubber, a polyacrylate elastomer, an epoxy elastomer, or combinations thereof, but is not limited thereto. The curing agent may be a silicone-based curing agent, an isocyanate, a peroxide, a UV curing agent, amines, or a combination thereof, but is not limited thereto.

The surface roughness of the tip 50a after curing may be controlled depending on the ratio of the elastic polymer precursor and the curing agent. For example, the higher the ratio of the elastic polymer precursor to the curing agent, the higher the surface roughness of the tip 50a. For example, the elastic polymer precursor and the curing agent may be included in a weight ratio of about 5:1 to about 20:1, and within that range may be included in a weight ratio of about 5:1 to about 15:1 or about 10:1 to about 20:1.

When the elastic polymer precursor and the curing agent are included in the above ranges, a relatively high surface roughness may be achieved. For example, the surface roughness of the upper surface 50au of the tip 50a in contact with the perovskite precursor solution described later may be greater than or equal to about 1.0 nm, within the above range, may be greater than or equal to about 1.2 nm, greater than or equal to about 1.5 nm, greater than or equal to about 1.8 nm, or greater than or equal to about 2.0 nm, and within the above range, may be about 1.0 nm to about 5.0 nm, about 1.2 nm to about 5.0 nm, about 1.5 nm to about 5.0 nm, about 1.8 nm to about 5.0 nm, about 2.0 nm to about 5.0 nm, about 1.0 nm to about 4.5 nm, about 1.2 nm to about 4.5 nm, about 1.5 nm to about 4.5 nm, about 1.8 nm to about 4.5 nm, about 2.0 nm to about 4.5 nm, about 1.0 nm to about 4.0 nm, about 1.2 nm to about 4.0 nm, about 1.5 nm to about 4.0 nm, about 1.8 nm to about 4.0 nm, about 2.0 nm to about 4.0 nm, about 1.0 nm to about 3.0 nm, about 1.2 nm to about 3.0 nm, about 1.5 nm to about 3.0 nm, about 1.8 nm to about 3.0 nm, or about 2.0 nm to about 3.0 nm. Herein, the surface roughness may be measured using an atomic force microscope (AFM), for example, by scanning the topology of the upper surface 50au of the tip 50a using a non-contact AFM tip and calculating the root mean square (RMS) based on the upper surface profile data.

The surface roughness of the tip 50a within the ranges may not only increase the coverage of the perovskite precursor solution 80 on the upper surface 50au of the tip 50a in the step of applying the perovskite precursor solution 80 to be described later, but also increase a size and a uniformity of nanocrystals in the step of crystallizing perovskite to be described later.

Specifically, when the upper surface 50au of the tip 50a has surface roughness within the ranges, since adhesion and spreading of the perovskite precursor solution 80 on the upper surface 50au of the tip 50a may be increased, the coverage of the perovskite precursor solution 80 on the upper surface 50au of the tip 50a may be increased, for example, the coverage of the perovskite precursor solution 80 may be greater than or equal to about 80%, greater than or equal to about 85%, greater than or equal to about 90%, greater than or equal to about 95%, greater than or equal to about 98%, greater than or equal to about 99%, or greater than or equal to about 100%, on the upper surface 50au of the tip 50a. In addition, when the upper surface 50au of the tip 50a has surface roughness within the ranges, since a heterogeneous nucleation energy barrier forming crystals may be effectively reduced, the perovskite nanocrystals may grow into a relatively small and uniform size of less than about 100 nm.

For example, the surface roughness within the ranges may be more effectively controlled through Soxhlet extraction. The Soxhlet extraction is a process of dissolving and removing non-cross-linked oligomers by using a volatile solvent such as acetone. For example, due to a rapid heat transfer of the mold 30, uncured oligomers may remain inside the tip 50a, and also, some uncured oligomers may exist at the surface of the tip 50a. When removing the uncured oligomer inside the tip 50a through the Soxhlet extraction, fine pores may be created inside the tip 50a, due to a rearrangement of the fine pores and the removal of the uncured oligomer, the surface roughness of the upper surface of the tip 50a may be increased and the surface roughness in the aforementioned range may be implemented.

By controlling the surface roughness of the tip 50a in this way, a wetting angle of the perovskite precursor solution 80 on the upper surface 50au of the tip 50a may be effectively controlled in the step of applying the perovskite precursor solution 80, thereby improving the adhesion and spreading of the perovskite precursor solution 80 on the upper surface 50au of the tip 50a and simultaneously, effectively reducing the heterogeneous nucleation energy barrier forming crystals. Through this, perovskite nanocrystals with a relatively small and uniform size of less than about 100 nm may be grown, as described later.

The elastic polymer solution 40 may be supplied, for example, by spin coating, slit coating, Inkjet coating, nozzle printing, spraying, dripping, and/or doctor blade coating, but is not limited thereto. The elastic polymer solution 40 may be filled in the recesses 30a of the mold 30.

Next, the elastic polymer solution 40 supplied on the mold 30 is covered with a support substrate 70 and the elastic polymer solution 40 is cured. The curing may be thermal curing or photocuring. The thermal curing may be performed, for example, at about 60° C. to about 80° C. for about 12 hours to about 18 hours, and the photocuring may be performed, for example, by irradiating with ultraviolet (UV) light at a wavelength of about 365 nm for about 2 minutes to about 4 minutes, but is not limited thereto. The elastic polymer solution 40 filled in the recesses 30a of the mold 30 may be cured and cast into the tip array 50 including a plurality of tips 50a having substantially the same shape and size as the recesses 30a.

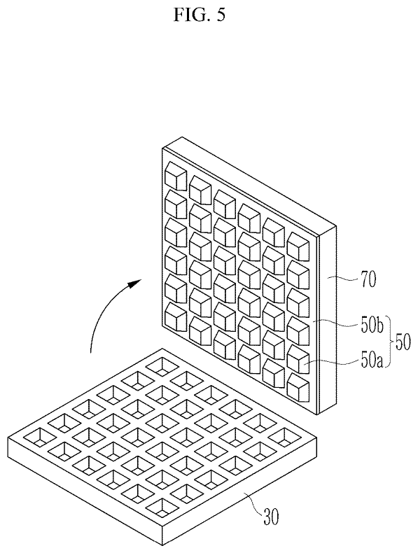

Referring to FIG. 5, the cured tip array 50 is separated from the mold 30. The cured tip array 50 may include the plurality of tips 50a arranged along rows and/or columns or randomly and a lower layer 50b with a predetermined thickness that is connected as a whole, as shown in FIG. 1.

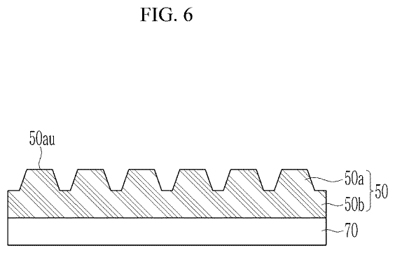

Referring to FIG. 6, each tip 50a may have a truncated pyramidal shape with a flat upper surface 50au, and the cross section of each tip 50a may have a trapezoidal or trapezoid-like shape. The width, length, or diameter d of the upper surface 50au of the tip 50a may be substantially equal to the width, length, or diameter of the perovskite crystal pattern 120a to be formed. As described above, at least one of the width and length of the tip 50a (e.g., each of the width and length) or the diameter d may be less than about 50 μm, and within the above range may be less than or equal to about 45 μm, less than or equal to about 40 μm, less than or equal to about 35 μm, less than or equal to about 30 μm, less than or equal to about 25 μm, less than or equal to about 20 μm, less than or equal to about 15 μm, less than or equal to about 10 μm, less than or equal to about 9 μm, or less than or equal to about 8 μm, within the above range, greater than or equal to about 0.01 μm and less than about 50 μm, about 0.01 μm to about 45 μm, about 0.01 μm to about 40 μm, about 0.01 μm to about 35 μm, about 0.01 μm to about 30 μm, about 0.01 μm to about 25 μm, about 0.01 μm to about 20 μm, about 0.01 μm to about 15 μm, about 0.01 μm to about 10 μm, about 0.01 μm to about 9 μm, about 0.01 μm to about 8 μm, greater than or equal to about 0.1 μm and less than about 50 μm, about 0.1 μm to about 45 μm, about 0.1 μm to about 40 μm, about 0.1 μm to about 35 μm, about 0.1 μm to about 30 μm, about 0.1 μm to about 25 μm, about 0.1 μm to about 20 μm, about 0.1 μm to about 15 μm, about 0.1 μm to about 10 μm, about 0.1 μm to about 9 μm, or about 0.1 μm to about 8 μm.

The tip array 50 may include a cured elastomeric polymer, for example, polydimethylsiloxane PDMS. The PDMS may generally have a hydrophobic surface, and thus the tip array 50 without any surface treatment may have a relatively low surface energy and a relatively high contact angle (water contact angle) of, for example, about 25 to about 150 degrees.

For example, the tip array 50 may be modified to be hydrophilic, before supplying the perovskite precursor solution 80 described later, and the modification to be hydrophilic may be performed by plasma, for example, oxygen plasma (O₂ plasma). The O₂ plasma may modify the surface of the tip array 50 to have strong hydrophilicity by replacing the methyl groups (—CH₃) with —O and/or —OH groups. The oxygen plasma treatment may be performed, for example, at about 5 W to about 80 W for about 30 seconds to about 30 minutes, or within the above range, at about 10 W to about 50 W for about 1 minute to about 20 minutes, or at about 30 W to about 40 W for about 3 minutes to about 4 minutes, but is not limited thereto. The contact angle of the upper surface of the tip array 50 modified to be hydrophilic by O₂ plasma treatment may be from 0 degrees to about 20 degrees.

The perovskite precursor solution 80 described later may include a polar solvent, and the perovskite precursor solution 80 including the polar solvent may adhere to the upper surface 50au of the hydrophilically modified tip array 50 with high wettability, and accordingly, may be formed to have substantially the same shape and size as the upper surface 50au of the tip array 50 in the annealing process described later, and may be grown as nanocrystals of a relatively uniform size.

Next, a perovskite precursor solution 80 is prepared. The perovskite precursor solution 80 includes a perovskite precursor, and may optionally further include a hydrophilic polymer, an ionic liquid, and/or a ligand.

The perovskite precursor solution 80 may be prepared, for example, by mixing cations and anions in a solvent. Herein, the perovskite precursor solution 80 may be prepared by separately preparing a cation solution in which a cation is dissolved in a solvent and an anion solution in which an anion is dissolved in a solvent, and then mixing the cation solution and the anion solution, or by mixing a cation and an anion in a solvent.

The cation may be supplied in a form of a compound that is capable of supplying, for example a monovalent inorganic cation such as Lit, Na⁺, K⁺, Rb⁺, and Cs⁺; a monovalent organic cation such as an organic ammonium cation and an organic amino cation; a divalent metal cation including a transition metal, a rare earth element, an alkaline-earth metal, or a combination thereof such as Pb²⁺, Sn²⁺, Ge²⁺, Ga²⁺, In²⁺, Al²⁺, Sb²⁺, Bi²⁺, and PO²⁺; or a combination thereof. The anion may be supplied in a form of a compound that is capable of supplying, for example, a halide anion. For example, the monovalent organic cation may be alkylammonium, arylammonium, arylalkylammonium, alkylamidinium, arylamidinium, arylalkylamidinium, or a combination thereof, for example, methylammonium, formamidinium, or phenylammonium, n-butyl ammonium, 2-phenylmethylammonium, or 2-phenylethylammonium, for example, CH₃NH₃, HC(NH₂)₂, C₄H₉NH₃, C₆H₅CH₂NH₃, C₆H₅C₂H₄NH₃, C₆H₁₃NH₃, or a combination thereof, but is not limited thereto. The divalent metal cation may be, for example, Pb²⁺ or Sn²⁺, and the halide anion may be, for example, F⁻, Cl⁻, Br⁻, or I⁻.

The hydrophilic polymer may further reduce the surface energy between the perovskite precursor solution 80 and the tip array 50, thereby further increasing the wettability of the perovskite precursor solution 80 on the tip array 50, and allowing the perovskite precursor solution 80 to adhere closely to the upper surface 50au of the tip 50a to form a perovskite crystal pattern 120a having substantially the same shape and size as the upper surface of the tip 50a.

The hydrophilic polymer may include polyvinylpyrrolidone (PVP), polyethylenimine (PEI), polyacrylamide (PAM), poly(meta)acrylate, polyvinylalcohol (PVA), polyethylene glycol, polyethyleneoxide, polyoxazoline, a derivative thereof, or a copolymer thereof, but is not limited thereto.

The ionic liquid may increase stability of the perovskite nanocrystals and may be 1-butyl-3-methylimidazolium tetrafluoroborate (BMIMBF₄), poly(2-acrylamino-2-methylpropane sulfonic acid), poly(ethylene oxide), 1-butyl-3-methylimidazolium bis(trifluoromethylsulfonyl)imide (BMIMTFSI), or a combination thereof, but is not limited thereto.

As described later, the ligand may effectively control crystal growth from the perovskite precursor in the process of crystallizing the perovskite precursor by annealing to form a perovskite crystal pattern 120a including nanocrystals, thereby allowing the perovskite nanocrystals to grow relatively uniformly with a crystal size of sub-micrometers.

The solvent is not particularly limited as long as it may dissolve or disperse the aforementioned components. The solvent may be, for example, an organic solvent, for example, dimethylformamide, dimethylsulfoxide, or a combination thereof, but is not limited thereto.

The perovskite precursor, the hydrophilic polymer, the ionic liquid, the ligand, and the solvent may be included in amounts of about 5 to about 50 wt %, about 1 to about 30 wt %, about 0.001 to about 10 wt %, about 0.001 to about 10 wt %, and in a balance amount, respectively, based on the total amount of the perovskite precursor solution.

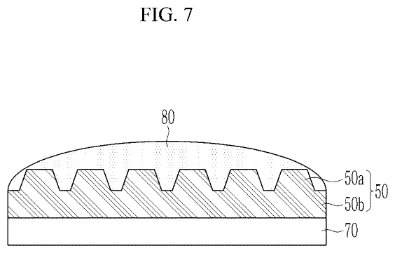

Next, referring to FIG. 7, a perovskite precursor solution 80 is applied on the tip array 50. The application of the perovskite precursor solution 80 may be performed by a solution process, such as spin coating, slit coating, inkjet coating, nozzle printing, spraying, dropping, and/or doctor blade coating, but is not limited thereto.

Next, the tip array 50 to which the perovskite precursor solution 80 is applied is annealed. The annealing may be performed, for example, at a temperature of about 50 to about 200° C. for about 1 minute to about 10 hours, but is not limited thereto.

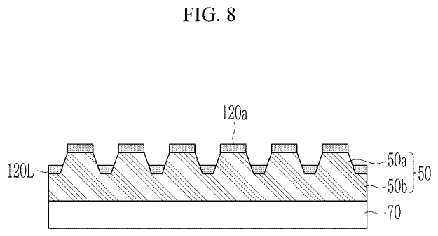

Referring to FIG. 8, the solvent is removed from the perovskite precursor solution 80 by annealing, and perovskite crystal patterns 120a and 120L including perovskite nanocrystals grown from the perovskite precursor may be formed. The perovskite crystal pattern 120a may be a portion formed on the upper surface of each tip 50a of the tip array 50, and the perovskite crystal pattern 120L may be the remaining portion excluding the perovskite crystal patterns 120a. The coverage of the perovskite crystal pattern 120a covering the upper surface 50au of the tip 50a may be relatively high, for example, the width of the perovskite crystal pattern 120a may be greater than or equal to about 80%, greater than or equal to about 85%, greater than or equal to about 90%, greater than or equal to about 95%, greater than or equal to about 98%, greater than or equal to about 99%, or about 100% of the width of the upper surface 50au of the tip 50a.

The perovskite nanocrystal may have a sub-micrometer crystal size, and for example, the average crystal size of the perovskite nanocrystals may be less than about 100 nm, less than about 80 nm, or less than about 50 nm, and within the range, may be greater than or equal to about 2 nm and less than about 100 nm, about 2 nm to about 80 nm, or about 2 nm to about 50 nm. Due to the sub-micrometer crystal size, defects in the crystal may be reduced to prevent a decrease in luminous efficiency at room temperature.

The perovskite nanocrystals may have a relatively uniform crystal size. For example, the standard deviation of the crystal size of the perovskite nanocrystals may be less than or equal to about 50%, less than or equal to about 40%, less than or equal to about 30%, less than or equal to about 20%, or less than or equal to about 10% of the average crystal size.

The perovskite nanocrystals may have a crystal structure including cations and anions, for example, a layered structure or a non-layered structure. The perovskite nanocrystals may have a crystal structure represented by, for example, ABX₃, A₂BX₄, ABX₄, Aₙ₋₁BₙX₃ₙ₊₁, or L₂Aₙ₋₁BₙX₃ₙ₊₁ (0<n≤1), but is not limited thereto. Herein, A may be a monovalent inorganic cation such as Lit, Na⁺, K⁺, Rb⁺, and Cs⁺; a monovalent organic cation such as an organic ammonium cation and an organic amino cation; or a combination thereof, and B may be a metal cation including a transition metal such as Pb²⁺, Sn²⁺, Ge²⁺, Ga²⁺, In²⁺, Al²⁺, Sb²⁺, Bi²⁺, and Po²⁺, a rare earth metal, an alkaline earth metal, or a combination thereof, X may be an oxygen anion or a halide anion such as F⁻, Cl⁻, Br⁻, or I⁻, and L may be an aliphatic or aromatic ammonium cation or an aliphatic or aromatic amino cation which is different from A. The organic ammonium cation or organic amino cation may be, for example, methylammonium, formamidinium, or phenylammonium, but is not limited thereto. The aliphatic or aromatic ammonium cation or the aliphatic or aromatic amino cation may be, for example, n-butyl ammonium, 2-phenylmethyl ammonium, or 2-phenylethyl ammonium, but is not limited thereto.

For example, the perovskite nanocrystals may be halide perovskite nanocrystals including halide anions.

For example, the perovskite nanocrystals may be organic-inorganic hybrid perovskite nanocrystals including organic cations and metal cations.

For example, the perovskite nanocrystals may be CH₃NH₃PbBr₃, CH₃NH₃PbI₃, CH₃NH₃SnBr₃, CH₃NH₃SnI₃, CH₃NH₃Sn₁₋ₓPbₓBr₃, CH₃NH₃Sn₁₋ₓPbₓI₃, HC(NH₂)₂PbI₃, HC(NH₂)₂SnI₃, (C₄H₉NH₃)₂PbBr₄, (C₆H₅CH₂NH₃)₂PbBr₄, (C₆H₅CH₂NH₃)₂PbI₄, (C₆H₅C₂H₄NH₃)₂PbBr₄, (C₆H₁₃NH₃)₂(CH₃NH₃)ₙ₋₁PbₙI₃ₙ₊₁, or a combination thereof, but are not limited thereto.

As an example, the perovskite crystal patterns 120a and 120L may include perovskite nanocrystals, and optionally the hydrophilic polymer, the ionic liquid, and/or the ligand bound to or coordinated to the surface of the perovskite nanocrystals.

The hydrophilic polymer may prevent degradation by oxygen and/or moisture by reducing the exposure of the perovskite nanocrystals to oxygen and/or moisture in the air within the perovskite crystal patterns 120a and 120L.

The hydrophilic polymer may be included in the perovskite crystal pattern 120a, 120L in an amount equal to or less than the perovskite nanocrystals, for example, may be included in an amount of about 0.1 to 100 parts by weight based on 100 parts by weight of the perovskite nanocrystals, within the range, about 1 to 80 parts by weight, about 1 to 50 parts by weight, about 1 to 30 parts by weight, or 1 to 20 parts by weight based on 100 parts by weight of the perovskite nanocrystals.

The ligand may be bound or coordinated to the surface of the perovskite nanocrystals. The ligand may be, for example, an organic ligand, and may be derived from, for example, aliphatic hydrocarbons and/or aromatic hydrocarbons. The ligand may be for example derived from RCOOH, RNH₂, R₂NH, R₃N, RSH, RH₂PO, R₂HPO, R₃PO, RH₂P, R₂HP, R₃P, ROH, RCOOR, RPO(OH)₂, RPOOH, RHPOOH, or R₂POOH (wherein, R may independently be a substituted or unsubstituted C1 to C40 aliphatic hydrocarbon, a substituted or unsubstituted C6 to C40 aromatic hydrocarbon, or a combination thereof). The ligand may be, for example, derived from methane thiol, ethane thiol, propane thiol, butane thiol, pentane thiol, hexane thiol, octane thiol, dodecane thiol, hexadecane thiol, octadecane thiol, benzyl thiol; methane amine, ethane amine, propane amine, butyl amine, pentyl amine, hexyl amine, octyl amine, dodecyl amine, hexadecyl amine, octadecyl amine, dimethyl amine, diethyl amine, dipropyl amine, oleyl amine; methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid; phosphine such as a substituted or unsubstituted methyl phosphine (e.g., trimethyl phosphine, methyldiphenyl phosphine, etc.), a substituted or unsubstituted ethyl phosphine (e.g., triethyl phosphine, ethyldiphenyl phosphine, etc.), a substituted or unsubstituted propyl phosphine, a substituted or unsubstituted butyl phosphine, a substituted or unsubstituted pentyl phosphine, a substituted or unsubstituted octylphosphine (e.g., trioctylphosphine (TOP)), and the like; phosphine oxide such as a substituted or unsubstituted methyl phosphine oxide (e.g., trimethyl phosphine oxide, methyldiphenyl phosphineoxide, etc.), a substituted or unsubstituted ethyl phosphine oxide (e.g., triethyl phosphine oxide, ethyldiphenyl phosphineoxide, etc.), a substituted or unsubstituted propyl phosphine oxide, a substituted or unsubstituted butyl phosphine oxide, a substituted or unsubstituted octylphosphine oxide (e.g., trioctylphosphineoxide (TOPO), and the like; a diphenyl phosphine, triphenyl phosphine compound or an oxide compound thereof; C2 to C40 phosphonic acid; C2 to C40 phosphinic acid, and the like, but is not limited thereto.

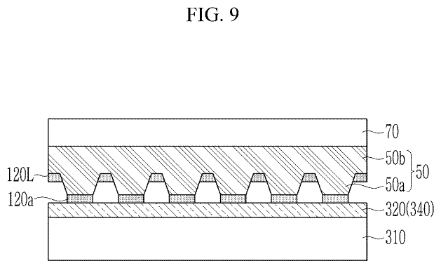

Referring to FIG. 9, the substrate 310 is disposed so as to face the tip array 50, and the plurality of perovskite crystal patterns 120a formed on the tip array 50 are brought into contact with the substrate 310. For example, an electrode 320 or a stack of an electrode 320 and a charge auxiliary layer 340 may be formed on a substrate 310, and the plurality of perovskite crystal patterns 120a may be in contact with the electrode 320 or the stack of the electrode 320 and the charge auxiliary layer 340.

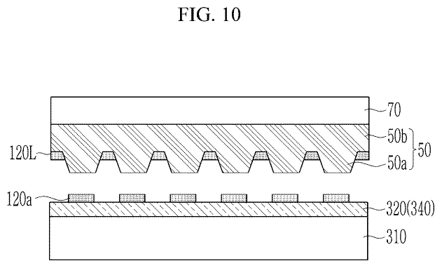

Referring to FIG. 10, the tip array 50 is removed from the substrate 310 and the plurality of perovskite crystal patterns 120a are transferred onto the substrate 310. For example, the electrode 320 or the stack of the electrode 320 and the charge auxiliary layer 340 may be formed on a substrate 310, and the plurality of perovskite crystal patterns 120a may be transferred onto the electrode 320 or the stack of the electrode 320 and the charge auxiliary layer 340. The plurality of transferred perovskite crystal patterns 120a may be formed as microstructures 120a on the substrate 310.

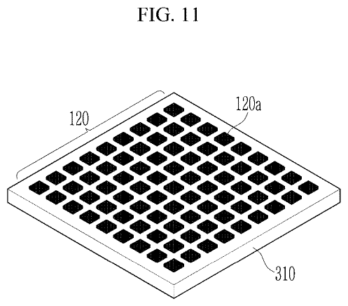

Accordingly, the microstructure array 120 in which the plurality of microstructures 120a are arranged on a substrate 310, as illustrated in FIG. 11, may be formed.

The size of each microstructure 120a may be substantially the same as the size of the upper surface 50au of the tip 50a and/or the size of the perovskite crystal pattern 120a, for example, at least one of the width and length (e.g., each of the width and length) or the diameter of each microstructure 120a may be, for example, less than about 50 μm, and within the above range may be less than or equal to about 45 μm, less than or equal to about 40 μm, less than or equal to about 35 μm, less than or equal to about 30 μm, less than or equal to about 25 μm, less than or equal to about 20 μm, less than or equal to about 15 μm, less than or equal to about 10 μm, less than or equal to about 9 μm, or less than or equal to about 8 μm, within the above range, greater than or equal to about 0.01 μm and less than about 50 μm, about 0.001 μm to about 45 μm, about 0.001 μm to about 40 μm, about 0.001 μm to about 35 μm, about 0.001 μm to about 30 μm, about 0.001 μm to about 25 μm, about 0.001 μm to about 20 μm, about 0.001 μm to about 15 μm, about 0.001 μm to about 10 μm, about 0.001 μm to about 9 μm, about 0.001 μm to about 8 μm, greater than or equal to about 0.01 μm and less than about 50 μm, about 0.01 μm to about 45 μm, about 0.01 μm to about 40 μm, about 0.01 μm to about 35 μm, about 0.01 μm to about 30 μm, about 0.01 μm to about 25 μm, about 0.01 μm to about 20 μm, about 0.01 μm to about 15 μm, about 0.01 μm to about 10 μm, about 0.01 μm to about 9 μm, about 0.01 μm to about 8 μm, greater than or equal to about 0.1 μm and less than about 50 μm, about 0.1 μm to about 45 μm, about 0.1 μm to about 40 μm, about 0.1 μm to about 35 μm, about 0.1 μm to about 30 μm, about 0.1 μm to about 25 μm, about 0.1 μm to about 20 μm, about 0.1 μm to about 15 μm, about 0.1 μm to about 10 μm, about 0.1 μm to about 9 μm, or about 0.1 μm to about 8 μm.

The microstructure 120a may be an island-shaped light emitter having a size (dimension) of several to several tens of micrometers, and may have a planar shape of, for example, a polygon such as a square, rectangle, hexagon or octagon, a circle, or an ellipse, but is not limited thereto.

For example, the microstructure 120a may be an island-shaped light emitter having a width and length of less than about 50 μm. For example, the microstructure 120a may be an island-shaped light emitter having a width and length of less than or equal to about 40 μm. For example, the microstructure 120a may be an island-shaped light emitter having a width and length of less than or equal to about 30 μm. For example, the microstructure 120a may be an island-shaped light emitter having a width and length of less than or equal to about 20 μm. For example, the microstructure 120a may be an island-shaped light emitter having a width and length of less than or equal to about 10 μm.

The microstructure 120a may be configured to emit light of a predetermined wavelength region within the visible light wavelength region, for example, may be configured to emit light of any one of a red wavelength region, a green wavelength region, and a blue wavelength region.

As described above, the microstructure array 120 including the plurality of microstructures 120a may be formed by transferring the perovskite crystal patterns 120a obtained by simultaneously performing perovskite crystallization and micropattern formation using the tip array 50 including the plurality of tips 50a having a truncated pyramidal shape with a flat upper surface 50au. Specifically, the perovskite precursor solution 80 may be supplied to the upper surface 50au of the plurality of tips 50a, which are regions to be formed with the perovskite crystal patterns 120a, and crystallized to effectively precipitate perovskite nanocrystals with a sub-micrometer crystal size. Accordingly, unlike the conventional perovskite crystallization step and micropattern formation step that are performed separately, the process may be simplified by performing perovskite crystallization and micropattern formation at once. In addition, since there is no process for patterning perovskite nanocrystals by photolithography or the like, the original characteristics of perovskite nanocrystals may be maintained without exposure to chemical solutions, so that the plurality of perovskite crystal patterns 120a may be uniformly formed without chemical deterioration.

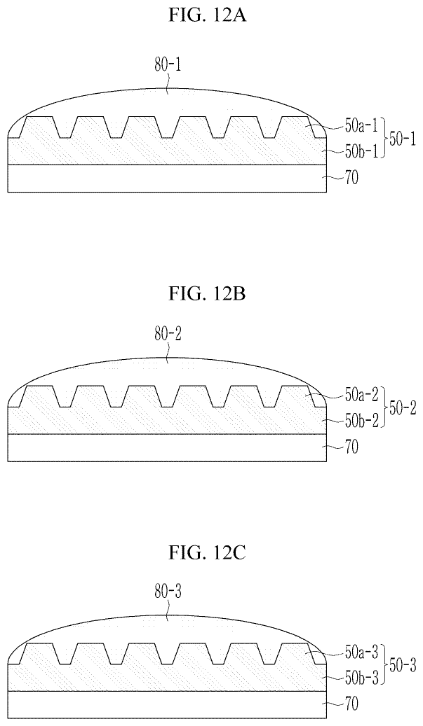

The microstructure array 120 may implement multi-color light emission by forming the microstructure array including the plurality of perovskite crystal patterns 120a that emits light of different wavelength regions. A method of manufacturing a microstructure array for multi-color light emission is described with reference to FIGS. 12A, 12B, 12C, 13A, 13B, 13C, and 14 to 17 with reference to FIGS. 1 to 11.

FIGS. 12A, 12B, 12C, 13A, 13B, 13C, and 14 to 17 are schematic views showing another example of a method of manufacturing a microstructure array according to embodiments.

First, according to the method illustrated in FIGS. 1 to 5, first, second and third tip arrays 50-1, 50-2, and 50-3 including a plurality of truncated pyramidal shaped tips 50a-1, 50a-2, and 50a-3 are formed using a mold 30 having a plurality of recesses 30a.

Referring to FIGS. 12A, 12B, and 12C, the first, second, and third tip arrays 50-1, 50-2, and 50-3 may each include an elastic polymer, for example, PDMS. For example, the surfaces of the first, second and third tip arrays 50-1, 50-2, and 50-3 may be hydrophilically modified by plasma treatment such as oxygen plasma, and the oxygen plasma treatment may be performed at, for example, about 5 W to about 80 W for about 30 seconds to about 30 minutes, or within the above range, at about 10 W to about 50 W for 1 minute to about 20 minutes, or at about 10 W to about 30 W for about 1 minute to about 10 minutes, but is not limited thereto.

Next, a first perovskite precursor solution 80-1 is applied on the first tip array 50-1 (FIG. 12A), a second perovskite precursor solution 80-2 is applied on the second tip array 50-2 (FIG. 12B), and a third perovskite precursor solution 80-3 is applied on the third tip array 50-3 (FIG. 12C).

The first perovskite precursor solution 80-1, the second perovskite precursor solution 80-2, and the third perovskite precursor solution 80-3 may each include the first, second, and third perovskite precursors, respectively, and optionally the hydrophilic polymer, the ionic liquid, and/or the ligand.

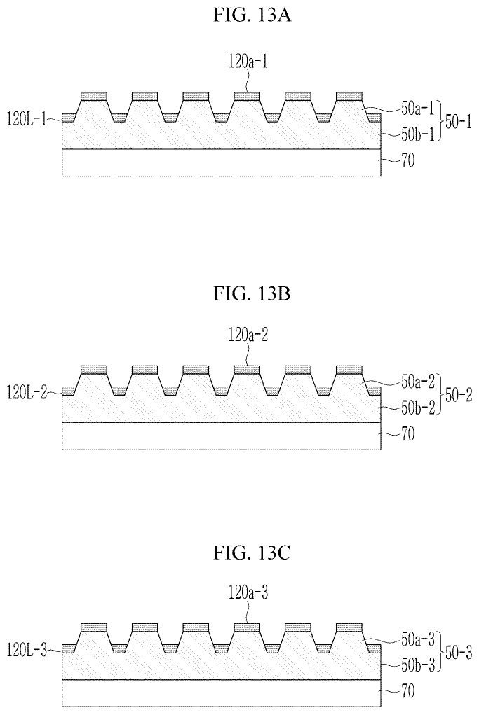

Referring to FIGS. 13A, 13B, and 13C, the first, second, and third tip arrays 50-1, 50-2, and 50-3 to which the first, second, and third perovskite precursor solutions 80-1, 80-2, and 80-3 are applied are annealed. The annealing may be performed, for example, at a temperature of about 50 to about 200° C. for about 1 minute to about 10 hours, but is not limited thereto.

By annealing, the solvent is removed from the first, second and third perovskite precursor solutions 80-1, 80-2, and 80-3, and first, second and third perovskite crystal patterns 120a-1, 120a-2, 120a-3, 120L-1, 120L-2, and 120L-3 including perovskite nanocrystals grown from the perovskite precursors may be formed. The first, second and third perovskite crystal patterns 120a-1, 120a-2, and 120a-3 may be portions formed on the upper surfaces of the first, second and third tips 50a-1, 50a-2, and 50a-3, and the first, second and third perovskite crystal patterns 120L-1, 120L-2, and 120L-3 may be the remaining portions.

The sizes of the first, second, and third perovskite crystal patterns 120a-1, 120a-2, and 120a-3 may be substantially equal to or smaller than the upper surface sizes of the tip arrays 50a-1, 50a-2, and 50a-3, for example, at least one of the width and the length (for example, each of the width and the length) of each of the first, second, and third perovskite crystal patterns 120a-1, 120a-2, and 120a-3 may be, for example, less than about 50 μm, and within the above range may be less than or equal to about 45 μm, less than or equal to about 40 μm, less than or equal to about 35 μm, less than or equal to about 30 μm, less than or equal to about 25 μm, less than or equal to about 20 μm, less than or equal to about 15 μm, less than or equal to about 10 μm, less than or equal to about 9 μm, or less than or equal to about 8 μm, within the above range, greater than or equal to about 0.01 μm and less than about 50 μm, about 0.01 μm to about 45 μm, about 0.01 μm to about 40 μm, about 0.01 μm to about 35 μm, about 0.01 μm to about 30 μm, about 0.01 μm to about 25 μm, about 0.01 μm to about 20 μm, about 0.01 μm to about 15 μm, about 0.01 μm to about 10 μm, about 0.01 μm to about 9 μm, about 0.01 μm to about 8 μm, greater than or equal to about 0.1 μm and less than about 50 μm, about 0.1 μm to about 45 μm, about 0.1 μm to about 40 μm, about 0.1 μm to about 35 μm, about 0.1 μm to about 30 μm, about 0.1 μm to about 25 μm, about 0.1 μm to about 20 μm, about 0.1 μm to about 15 μm, about 0.1 μm to about 10 μm, about 0.1 μm to about 9 μm, or about 0.1 μm to about 8 μm.

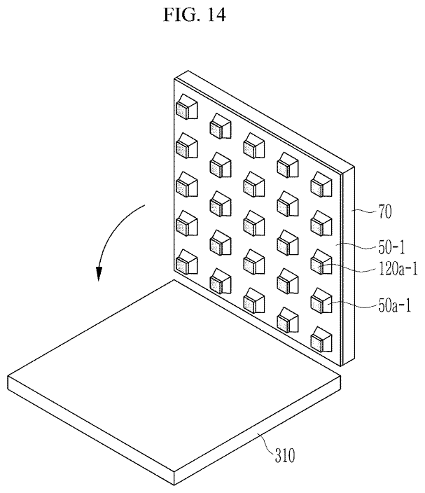

Referring to FIG. 14, a first tip array 50-1 is disposed on a substrate 310 so that the substrate 310 and the plurality of first perovskite crystal patterns 120a-1 may face each other. For example, an electrode or a stack of an electrode and a charge auxiliary layer may be on the substrate 310. The electrode may include a conductive metal oxide, such as zinc oxide, indium oxide, tin oxide, indium tin oxide (ITO), indium zinc oxide (IZO) or fluorine-doped tin oxide, or a thin single-layer or multi-layer metal film, and the charge auxiliary layer may be, for example, a hole injection layer, a hole transport layer, an electron blocking layer, an electron injection layer, an electron transport layer, and/or a hole blocking layer.

Subsequently the plurality of first perovskite crystal patterns 120a-1 are brought into contact with the upper surface of the substrate 310 (or an electrode or a stack of the electrode with a charge auxiliary layer), and the first tip array 50-1 may be removed to transfer the plurality of first perovskite crystal patterns 120a-1 onto the substrate 310. The first perovskite crystal patterns 120a-1 may be formed as a first microstructure 120a-1 on the substrate 310.

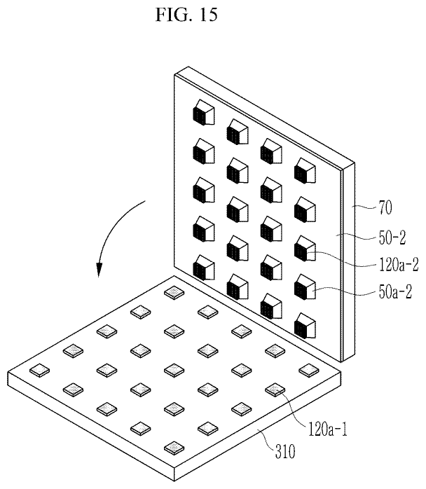

Subsequently, referring to FIG. 15, on the substrate 310 (or an electrode or a stack of the electrode and the charge auxiliary layer on the substrate 310) where the plurality of first perovskite crystal patterns 120a-1 are formed, a second tip array 50-2 where the plurality of second perovskite crystal patterns 120a-2 are arranged is disposed. Subsequently, the plurality of second perovskite crystal patterns 120a-2 are brought into contact with the substrate 310, and the second tip array 50-2 is removed to transfer the plurality of perovskite crystal patterns 120a-2 onto the substrate 310. The second perovskite crystal patterns 120a-2 may be formed as second microstructures 120a-2 on the substrate 310.

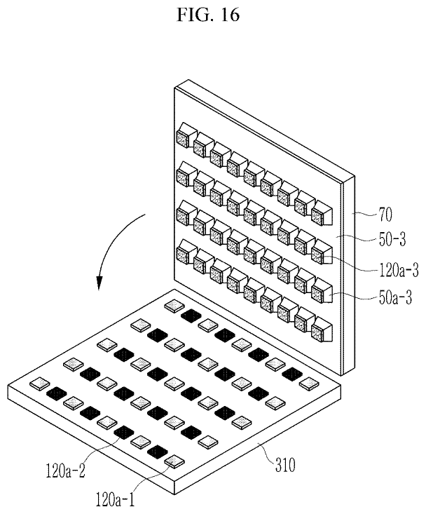

Subsequently, referring to FIG. 16, on the substrate 310 (or an electrode or a stack of the electrode and a charge auxiliary layer on the substrate 310) where the plurality of first and second microstructures 120a-1 and 120a-2 are formed, a third tip array 50-3 where the plurality of third perovskite crystal patterns 120a-3 are arranged is disposed. Subsequently, the plurality of third perovskite crystal patterns 120a-3 are brought into contact with the substrate 310, and the third tip array 50-3 is removed to transfer the plurality of third perovskite crystal patterns 120a-3 onto the substrate 310. The third perovskite crystal patterns 120a-3 may be formed as third microstructures 120a-3 on the substrate 310.

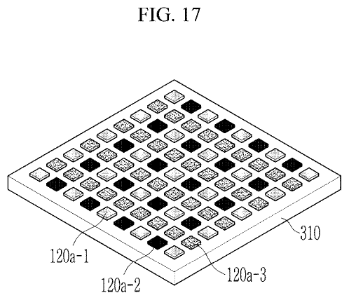

Accordingly, as shown in FIG. 17, the microstructure array 120 where the plurality of first, second, and third microstructures 120a-1, 120a-2, and 120a-3 are arranged may be formed.

The first, second, and third microstructures 120a-1, 120a-2, and 120a-3 may be configured to emit light of first, second, and third wavelength regions, which are different visible light wavelength regions from each other, wherein the first wavelength region may be, for example, a red wavelength region, the second wavelength region may be, for example, a green wavelength region, and the third wavelength region may be, for example, a blue wavelength region. The red wavelength region may have a peak wavelength λ_{peak,R} of, for example, greater than about 600 nm and less than about 750 nm, the green wavelength region may have a peak wavelength λ_{peak,G} of, for example, about 500 nm to about 600 nm, and the blue wavelength region may have a peak wavelength λ_{peak,B} of, for example, greater than or equal to about 380 nm and less than about 500 nm. Hereinafter, a micro light-emitting diode according to an embodiment is described with reference to the drawings.

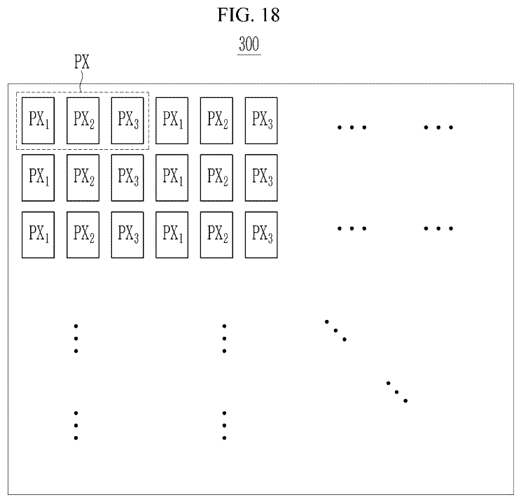

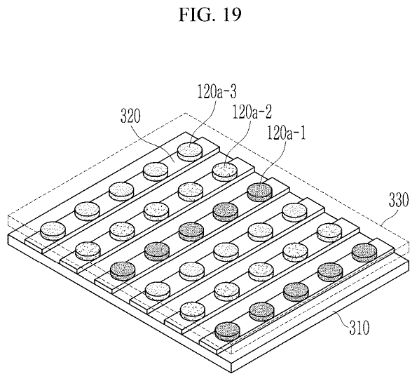

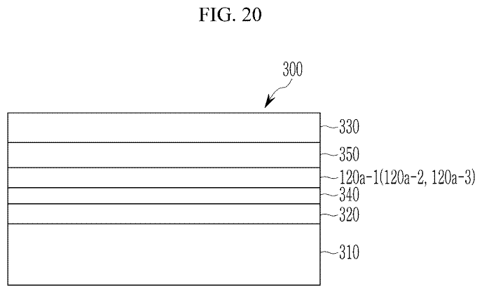

FIG. 18 is a schematic view showing an example of an arrangement of sub-pixels of a micro light-emitting diode according to an embodiment, FIG. 19 is a schematic view showing a micro light-emitting diode according to an embodiment, and FIG. 20 is a cross-sectional view showing one sub-pixel of the micro light-emitting diode of FIG. 19.

Referring to FIG. 18, the micro light-emitting diode 300 according to an embodiment includes a plurality of sub-pixels PX₁, PX₂, and PX₃, and the plurality of sub-pixels PX₁, PX₂, and PX₃ may have a matrix arrangement which is repeatedly arranged along columns and/or rows. The plurality of sub-pixels PX₁, PX₂, and PX₃ displaying different colors may form one pixel PX. For example, a sub-pixel displaying red, a sub-pixel displaying green, and a sub-pixel displaying blue may form one pixel. In FIG. 18, the arrangement of the rectangular sub-pixels PX₁, PX₂, and PX₃ repeatedly arranged along rows and columns is exemplarily illustrated, but the shape and arrangement of the sub-pixels PX₁, PX₂, and PX₃ are not limited thereto.

Each of the sub-pixels PX₁, PX₂, and PX₃ may have an island-shape with a dimension of several to several tens of micrometers, and may have a planar shape of a polygon such as a square, a rectangular, a hexagon, or an octagon, a circle or an elliptic, but are not limited thereto. Herein, the dimension may be a width and/or a length, and when the planar shape of the sub-pixels PX₁, PX₂, and PX₃ is a circle or elliptic, the width may be a diameter or a long diameter.

The dimension of the sub-pixels PX₁, PX₂, and PX₃ may be substantially the same as the dimension of the microstructures 120a. For example, the dimension of each of the sub-pixels PX₁, PX₂, and PX₃ may be less than about 50 μm, within the range, less than or equal to about 45 μm, less than or equal to about 40 μm, less than or equal to about 35 μm, less than or equal to about 30 μm, less than or equal to about 25 μm, less than or equal to about 20 μm, less than or equal to about 15 μm, less than or equal to about 10 μm, less than or equal to about 9 μm, or less than or equal to about 8 μm, and within the range, greater than or equal to about 0.01 μm and less than about 50 μm, about 0.01 μm to about 45 μm, about 0.01 μm to about 40 μm, about 0.01 μm to about 35 μm, about 0.01 μm to about 30 μm, about 0.01 μm to about 25 μm, about 0.01 μm to about 20 μm, about 0.01 μm to about 15 μm, about 0.01 μm to about 10 μm, about 0.01 μm to about 9 μm, about 0.01 μm to about 8 μm, greater than or equal to about 0.1 μm and less than about 50 μm, about 0.1 μm to about 45 μm, about 0.1 μm to about 40 μm, about 0.1 μm to about 35 μm, about 0.1 μm to about 30 μm, about 0.1 μm to about 25 μm, about 0.1 μm to about 20 μm, about 0.1 μm to about 15 μm, about 0.1 μm to about 10 μm, about 0.1 μm to about 9 μm, or about 0.1 μm to about 8 μm.

Referring to FIGS. 19 and 20, a micro light-emitting diode 300 according to an embodiment includes a substrate 310; a first electrode 320 formed on the substrate 310; first, second, and third microstructures 120a-1, 120a-2, and 120a-3 formed on the first electrode 320; and a second electrode 330 formed on the first, second, and third microstructures 120a-1, 120a-2, and 120a-3.

The first electrode 320 and the second electrode 330 may face each other, and one of the first electrode 320 and the second electrode 330 may be an anode and the other may be a cathode. For example, the first electrode 320 may be an anode and the second electrode 330 may be a cathode. For example, the first electrode 320 may be a cathode and the second electrode 330 may be an anode. The second electrode 330 may be, for example, a common electrode.

At least one of the first electrode 320 and the second electrode 330 may be a light-transmitting electrode, and the light-transmitting electrode may be made of, for example, zinc oxide, indium oxide, tin oxide, indium tin oxide (ITO), indium zinc oxide (IZO) or a conductive metal oxide such as fluorine-doped tin oxide, or a metal thin layer of a single layer or a multi-layer. When one of the first electrode 320 and the second electrode 330 is an opaque electrode, the opaque electrode may be made of an opaque conductor such as aluminum (AI), silver (Ag), or gold (Au).

The first, second, and third microstructures 120a-1, 120a-2, and 120a-3 are disposed between the first electrode 320 and the second electrode 330. The first, second, and third microstructures 120a-1, 120a-2, and 120a-3 may each include perovskite nanocrystals as described above, and may additionally include the hydrophilic polymer, the ionic liquid, and/or the ligand. The specific description is as described above, and the crystallization and pattern formation of perovskite may be performed at once according to the method described above.

The first, second, and third microstructures 120a-1, 120a-2, and 120a-3 may be arranged along rows or columns to form a microstructure array, and each may be configured to emit light of a different wavelength region from each other.

For example, the sub-pixel PX₁ may include the first microstructure 120a-1, the sub-pixel PX₂ may include the second microstructure 120a-2, and the sub-pixel PX₃ may include the third microstructure 120a-3. For example, the first, second, and third wavelength regions may be different wavelength regions from each other within the visible wavelength region, for example, one of the red wavelength region, the green wavelength region, and the blue wavelength region. For example, the first wavelength region may be a red wavelength region, the second wavelength region may be a green wavelength region, and the third wavelength region may be a blue wavelength region. The red wavelength region may have a peak wavelength λ_{peak,R} of, for example, greater than about 600 nm and less than about 750 nm, the green wavelength region may have a peak wavelength λ_{peak,G} of, for example, about 500 nm to about 600 nm, and the blue wavelength region may have a peak wavelength λ_{peak,B} of, for example, greater than or equal to about 380 nm and less than about 500 nm.

Referring to FIG. 20, a first charge auxiliary layer 340 may be formed between the first electrode 320 and the first, second, and third microstructures 120a-1, 120a-2, and 120a-3, and a second charge auxiliary layer 350 may be formed between the second electrode 330 and the first, second, and third microstructures 120a-1, 120a-2, and 120a-3. The first and second charge auxiliary layers 340 and 350 may be hole auxiliary layers or electron auxiliary layers, and may be, for example, hole injection layers, hole transport layers, electron blocking layers, electron injection layers, electron transport layers, and/or hole blocking layers. The first and second charge auxiliary layers 340 and 350 may include organic, inorganic, and/or organic-inorganic materials and may include one or more layers. One or both of the first and second charge auxiliary layers 340 and 350 may be omitted.

The micro light-emitting diode 300 may be a bottom emission emitting light toward the substrate 310, a top emission emitting light toward the opposite side of the substrate 310, or a dual emission emitting light toward both the substrate 310 and the opposite side of the substrate 310.

For example, when the first electrode 320 is a light-transmitting electrode and the second electrode 330 is a non-light-transmitting electrode, the micro light-emitting diode 300 may implement bottom emission.

For example, when the first electrode 320 is an opaque electrode and the second electrode 330 is a light-transmitting electrode, the micro light-emitting diode 300 may implement top emission.

For example, when the first electrode 320 and the second electrode 330 are each light emitting electrode, the micro light-emitting diode 300 may implement dual emission.

The first, second, and third microstructures 120a-1, 120a-2, and 120a-3 may be formed by simultaneously performing perovskite crystallization and micropattern formation using tip array 50-1, 50-2, and 50-3 including a plurality of tips 50a-1, 50a-2, and 50a-3 according to the method described above and then transferring the same.

A method of manufacturing a micro light-emitting diode 300 may further include forming a second charge auxiliary layer 350 and a second electrode 330 on the first, second, and third microstructures 120-1, 120-2, and 120-3, after forming of the first electrode 320, forming the first charge auxiliary layer 340, and forming the first, second, and third microstructures 120-1, 120-2, and 120-3. The second charge auxiliary layer 350 may be formed on the whole surface or may be arranged in multiple island or linear shapes depending on the shape of the second electrode 330.

The micro light-emitting diode may be applied to various electronic devices requiring light emission, such as display devices or lighting devices, but is not limited thereto.

Hereinafter, the embodiments are illustrated in more detail with reference to examples. However, these examples are exemplary, and the scope of claims is not limited thereto.

### Preparation of Blunt Tip Arrays

### Preparation Example 1

A Sylgard PDMS 184 base and a curing agent are mixed in a weight ratio of 5:1. Subsequently, the mixture is stirred for about 30 minutes to uniformly mix the base and the curing agent and then, treated with a vacuum desiccator for about 1 hour to remove bubbles to prepare a degassed PDMS precursor.

A quartz glass plate is washed and then, oxygen plasma-treated at an output of 30 W for 3 minutes. Subsequently, the PDMS precursor is coated on a Si mold having a plurality of recesses, covered with the oxygen plasma-treated quartz glass plate to be in contact with the PDMS precursor, and then, fixed with forceps at both ends. Herein, the recess of the Si mold has a truncated pyramidal shape whose up and down directions reversed and sides and bottom surface of the recess are formed at an angle of inclination of about 125.26 degrees.

Subsequently, the PDMS precursor is cured at about 60° C. in an oven for about 12 hours to 24 hours. Then, the cured PDMS is separated from the Si mold by using a laser blade to prepare a blunt tip array including a plurality of blunt tips formed on the quartz glass plate. Subsequently, the blunt tip array is dipped in an organic solvent (acetone and/or toluene) for 24 hours to perform a Soxhlet extraction.

### Preparation Example 2

A blunt tip array is prepared in the same manner as in Preparation Example 1 except that the Sylgard PDMS 184 base and the curing agent are mixed in a weight ratio of 10:1.

### Preparation Example 3

A blunt tip array is prepared in the same manner as in Preparation Example 1 except that the Sylgard PDMS 184 base and the curing agent are mixed in a weight ratio of 15:1.

### Preparation Example 4

A blunt tip array is prepared in the same manner as in Preparation Example 1 except that the Sylgard PDMS 184 base and the curing agent are mixed in a weight ratio of 20:1.

### Evaluation I

The blunt tip arrays obtained in Preparation Examples are evaluated with respect to a size and surface roughness.

The width and the surface roughness of the blunt tips are measured using an atomic force microscope (AFM, XE-150, Park Systems) based on upper surface profile data. Specifically, the surface roughness of the blunt tips may be obtained by scanning the topology of the upper surface of the blunt tips with a non-contact atomic force microscope (AFM) tip and calculating root mean square (RMS) based on the upper surface profile data.

The results are shown in Table 1.

TABLE 1

Blunt Tips

| | Width (μm) | Surface roughness (nm) |
|---|---|---|
| Preparation Example 1 | 9.9 | 1.4 |
| Preparation Example 2 | 9.8 | 2.5 |
| Preparation Example 3 | 9.8 | 2.7 |
| Preparation Example 4 | 9.75 | 2.8 |

Referring to Table 1, it may be confirmed that the blunt tip arrays according to Preparation Examples include blunt tips having an upper surface with a fine width of about 10 μm or less and a surface roughness of about 1.0 nm or more.

### Preparation of Perovskite Precursor Solution

### Preparation Example 5

43 mg of cesium bromide (CsBr, Sigma-Aldrich Co., Ltd.), 73 mg of lead bromide (PbBr₂, Sigma-Aldrich Co., Ltd.), 20 mg of phenylethylamine bromide (PEABr, Sigma-Aldrich Co., Ltd.), and 3 mg of dibenzo-18-crown-6 (Sigma-Aldrich Co., Ltd.) are dissolved in 1 mL of dimethyl sulfoxide (DMSO, Sigma-Aldrich Co., Ltd.) and then, sufficiently stirred in a sealed state at 60° C. on a hot plate with a stir bar to prepare a perovskite precursor solution for green light emission.

### Preparation Example 6

39 mg of cesium iodide (CsI, Sigma-Aldrich Co., Ltd.), 69 mg of lead iodide (PbI₂, Sigma-Aldrich Co., Ltd.), 37 mg of phenylethyl ammonium iodide (PEAI, Sigma-Aldrich Co., Ltd.), 3 mg of dibenzo-18-crown-6 (Sigma-Aldrich Co., Ltd.), and 3 mg of 1,3,5-tris(2-phenylbenzoimidazolyl)-benzene (TPBi, Sigma-Aldrich Co., Ltd.) are dissolved in 1 mL of dimethyl sulfoxide (DMSO, Sigma-Aldrich Co., Ltd.) and then, sufficiently stirred in a sealed state at 60° C. on a hot plate with a stir bar to prepare a perovskite precursor solution for red light emission.

### Preparation Example 7

26.8 mg of cesium chloride (CsCl, Sigma-Aldrich Co., Ltd.), 55.1 mg of lead bromide (PbBr₂, Sigma-Aldrich Co., Ltd.), 15.2 mg of phenylethyl ammonium bromide (PEABr, Sigma-Aldrich Co., Ltd.), and 3 mg of dibenzo-18-crown-6 (dibenzo-18-crown-6, Sigma-Aldrich Co., Ltd.) are dissolved in 1 mL of dimethyl sulfoxide (DMSO, Sigma-Aldrich Co., Ltd.) and then, sufficiently stirred in a sealed state at 60° C. on a hot plate with a stir bar to prepare a perovskite precursor solution for blue light emission.

### Manufacturing of Microstructure Array

### Example 1-1

The blunt tip array according to Preparation Example 2 is oxygen plasma-treated at an output of 30 W for 3 minutes. Subsequently, on the oxygen plasma-treated blunt tip array, the perovskite precursor solution for green light emission according to Preparation Example 5 is spin-coated sequentially at 1000 rpm for 5 seconds and at 3000 rpm for 40 seconds and then, annealed at 100° C. for 4 minutes to form green light-emitting perovskite crystal patterns on the upper surface of each of the blunt tips. Subsequently, the green light-emitting 5 perovskite crystal patterns are placed facing a PEDOT:PSS layer, which is a hole transport layer (HTL) formed on an ITO glass substrate, and brought into contact with each other, thereby transferring the green light emitting-perovskite crystal patterns on the upper surface of the blunt tips onto the PEDOT:PSS layer to form a plurality of microstructures for green light emission. Subsequently, after removing the blunt tip array, annealing is performed at 100° C. for 6 minutes to manufacture a green light-emitting microstructure array in which the plurality of green light-emitting microstructures are arranged on the glass substrate/ITO electrode/PEDOT:PSS layer.

### Example 1-2

A green light-emitting microstructure array is manufactured in the same manner as in Example 1-1 except that the blunt tip array according to Preparation Example 1 is used instead of the blunt tip array according to Preparation Example 2.

### Example 1-3

A green light-emitting microstructure array is manufactured in the same manner as in Example 1-1 except that the blunt tip array according to Preparation Example 3 is used instead of the blunt tip array according to Preparation Example 2.

### Example 1-4

A green light-emitting microstructure array is manufactured in the same manner as in Example 1-1 except that the blunt tip array according to Preparation Example 4 is used instead of the blunt tip array according to Preparation Example 2.

### Example 2

A red light-emitting microstructure array is manufactured in the same manner as in Example 1-1 except that the red light-emitting perovskite precursor solution of Preparation Example 6 is used instead of the green light-emitting perovskite precursor solution of Preparation Example 5 and then, annealed at 100° C. for 2 minutes to form red light-emitting perovskite crystal patterns on the upper surface of each of the blunt tips.

### Example 3

A blue light-emitting microstructure array is manufactured in the same manner as in Example 1-1 except that the blue light-emitting perovskite precursor solution of Preparation Example 7 is used instead of the green light-emitting perovskite precursor solution of Preparation Example 5 and then, annealed at 100° C. for 1 minute to form blue light-emitting perovskite crystal patterns on the upper surface of the blunt tips.

### Example 4

A red light-emitting microstructure array is manufactured in the same manner as in Example 1-1 except that the blunt tip array of Preparation Example 2 is oxygen plasma-treated (30 W, 3 minutes), and the red light-emitting perovskite precursor solution of Preparation Example 6 is spin-coated on the oxygen plasma-treated blunt tip array sequentially at 1000 rpm for 5 seconds and at 3000 rpm for 40 seconds and then, annealed at 100° C. for 2 minutes to form red light-emitting perovskite crystal patterns on the upper surface of each of the blunt tips. Subsequently, the red light-emitting perovskite crystal patterns are placed facing a PEDOT:PSS layer (HTL) on an ITO glass substrate, and brought into contact with each other, thereby transferring the red light-emitting perovskite crystal patterns on the upper surface of the blunt tips onto the PEDOT:PSS layer to form a plurality of red light-emitting microstructures. Subsequently, the blunt tip array is removed.

Subsequently, after oxygen plasma-treating (30 W, 3 minutes) the blunt tip array obtained in Preparation Example 2, the green light-emitting perovskite precursor solution of Preparation Example 5 is spin-coated sequentially at 1000 rpm for 5 seconds and at 3000 rpm for 40 seconds on the oxygen plasma-treated blunt tip array and then, annealed at 100° C. for 4 minutes to form green light-emitting perovskite crystal patterns on the upper surface of each of the blunt tips. Subsequently, the green light-emitting perovskite crystal patterns are placed facing the PEDOT:PSS layer (HTL) on the substrate on which the plurality of red light-emitting microstructures are formed, and after positioning them with an optical microscope (upright metal microscope, LV100ND, Nikon), brought into contact with each other, thereby transferring the green light-emitting perovskite crystal patterns formed on the upper surface of each of the blunt tips onto the PEDOT:PSS layer to form a plurality of green light-emitting microstructures. Subsequently, the blunt tip array is removed.

Subsequently, after oxygen plasma-treating (30 W, 3 minutes) the blunt tip array obtained in Preparation Example 2, the blue light-emitting perovskite precursor solution of Preparation Example 7 is spin-coated sequentially at 1000 rpm for 5 seconds and at 3000 rpm for 40 seconds on the oxygen plasma-treated blunt tip array and then, annealed at 100° C. for 1 minute to form blue light-emitting perovskite crystal patterns on the upper surface each of the blunt tips. Subsequently, the blue light-emitting perovskite crystal patterns are placed facing the PEDOT:PSS layer (HTL) on the substrate on which the plurality of red light-emitting microstructures and the plurality of green light-emitting microstructures are formed, and after positioning them by using an optical microscope (upright metal microscope, LV100ND, Nikon), brought into contact with each other, thereby transferring the blue light-emitting perovskite crystal patterns on the upper surface of each of the blunt tips onto the PEDOT:PSS layer to form a plurality of blue light-emitting microstructures on the PEDOT:PSS layer. Subsequently, the blunt tip array is removed, and annealing is performed at 100° C. for 6 minutes to manufacture a microstructure array for multi-color light emission in which the plurality of red light-emitting microstructures, the plurality of green light-emitting microstructures, and the plurality of blue light-emitting microstructures are arranged on the glass substrate/ITO electrode/PEDOT:PSS layer.

### Reference Example 1

The green light-emitting perovskite precursor solution of Preparation Example 5 is spin-coated on an ITO glass substrate coated with a PEDOT:PSS layer (HTL) sequentially at 1000 rpm for 5 seconds and at 3000 rpm for 40 seconds and then, annealed at 100° C. for 10 minutes to form a green light-emitting film.

### Reference Example 2

The red light-emitting perovskite precursor solution of Preparation Example 2 is spin-coated on an ITO glass substrate coated with a PEDOT:PSS layer (HTL) sequentially at 1000 rpm for 5 seconds and at 3000 rpm for 40 seconds and then, annealed at 100° C. for 10 minutes to form a red light-emitting film.

### Reference Example 3

The blue light-emitting perovskite precursor solution of Preparation Example 3 is spin-coated on an ITO glass substrate coated with a PEDOT:PSS layer (HTL) sequentially at 1000 rpm for 5 seconds and at 3000 rpm for 40 seconds and then, annealed at 100° C. for 10 minutes to form a blue light-emitting film.

### Evaluation II

The perovskite crystal patterns on the upper surface of each blunt tip used in Examples 1-1 to 1-4 are evaluated with respect to widths.

The widths of the perovskite crystal patterns are measured by taking an image of by using an optical microscope (OM, an upright metal microscope, LV100ND, Nikon).

The results are shown in Table 2.

TABLE 2

| | Pattern width (μm) |
|---|---|
| Example 1-1 | 8.4 |
| Example 1-2 | 8.1 |
| Example 1-3 | 8.5 |
| Example 1-4 | 8.8 |

Referring to Table 2, it may be confirmed that the perovskite crystal patterns formed on the upper surface of each blunt tip have a width of about 80% or more of width of each blunt tip (refer to Table 1), and from this, it may be confirmed that the perovskite crystal patterns are formed with a high coverage on the upper surface of each blunt tip.

### Evaluation III

The microstructure arrays according to Examples and the light emitting films according to Reference Examples are evaluated with respect to emission spectra and life-span characteristics during the emission.

The emission spectra are evaluated by using a benchtop spectrophotometer (HORIBA FluoroMax, HORIBA Instruments). Herein, a xenon lamp is used as a light source, and the emission spectra are measured after emitting red, green, and blue light by extracting red light of a wavelength of 425 nm, green light of a wavelength of 350 nm, and blue light of a wavelength of 325 nm through a filter.

The life-span characteristics are evaluated by measuring time-resolved photoluminescence (TRPL) decay curve in a TCSPC (Time-Correlated Single Photon Counting) mode of HORIBA FluoroMax equipment. For this purpose, the light source is changed from the xenon lamp to a HORIBA NanoLED pulse laser, wherein a pulse laser with a wavelength of 402 nm is use as an excitation source.

The results are shown in Tables 3 to 5.

TABLE 3

| | Maximum | Full width | Average |
|---|---|---|---|
| | emission | at half | carrier |
| | wavelength | maximum | life-span |
| | (nm) | (FWHM, nm) | (ns) |
| Example 1-1 | 511 | 25.93 | 35.90 |
| Reference Example 1 | 513 | 20.57 | 14.41 |

TABLE 4

| | Maximum | Full width | Average |
|---|---|---|---|
| | emission | at half | carrier |
| | wavelength | maximum | life-span |
| | (nm) | (FWHM, nm) | (ns) |
| Example 2 | 686 | 40.98 | 12.97 |
| Reference Example 2 | 668 | 37.24 | 4.94 |

TABLE 5

| | Maximum | Full width | Average |
|---|---|---|---|
| | emission | at half | carrier |
| | wavelength | maximum | life-span |
| | (nm) | (FWHM, nm) | (ns) |
| Example 3 | 478 | 20.31 | 2.23 |
| Reference Example 3 | 482 | 21.06 | 1.15 |

Referring to Tables 3 to 5, the microstructure arrays according to Examples, compared with the light emitting films according to Reference Examples, exhibit an improved average carrier lifetime as well as an equivalent emission spectrum.

### Manufacturing of Micro Light-Emitting Diode

### Example 5

60 nm of 2,2′,2″-(1,3,5-benzinetriyl)-tris(1-phenyl-1-H-benzimidazole) (TPBi) (ETL), 1 nm of LiF (EIL), and 100 nm of aluminum (electrode) are sequentially deposited on the green light-emitting microstructure array according to Example 1-1 in a high vacuum state (10-8 Torr or less) to manufacture a green light-emitting micro light-emitting diode.

### Example 6

60 nm of TPBi (ETL), 1 nm of LiF (EIL), and 100 nm of aluminum (electrode) are sequentially deposited on the red light-emitting microstructure array according to Example 2 in a high vacuum state (10-8 Torr or less) to manufacture a red light-emitting micro light-emitting diode.

### Example 7

60 nm of TPBi (ETL), 1 nm of LiF (EIL), and 100 nm of aluminum (electrode) are sequentially deposited on the blue light-emitting microstructure array according to Example 3 in a high vacuum state (10-8 Torr or less) to manufacture a red light-emitting micro light-emitting diode.

### Example 8

60 nm of TPBi (ETL), 1 nm of LiF (EIL), and 100 nm of aluminum (electrode) are sequentially deposited on the multi-color light-emitting microstructure array according to Example 4 in a high vacuum state (10-8 Torr or less) to manufacture a multi-color light-emitting micro light-emitting diode.

### Evaluation IV

The micro light-emitting diodes according to Examples are evaluated with respect to electroluminescence.

The electroluminescence of the micro light-emitting diodes is evaluated by using an electroluminescence (EL) measurement system (Dongwoo Optron Co., Ltd.) and an optical microscope (an upright metal microscope, LV100ND, Nikon).

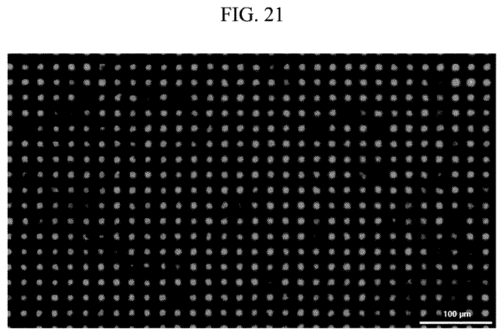

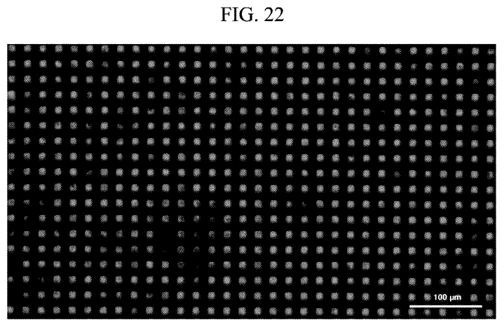

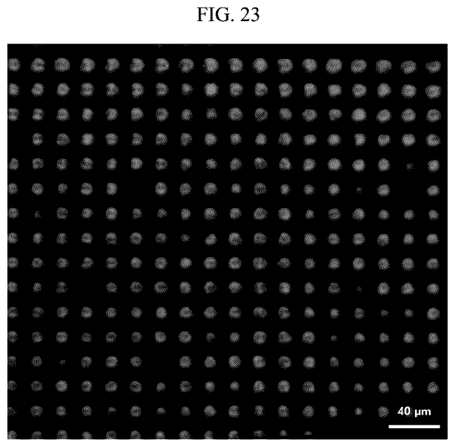

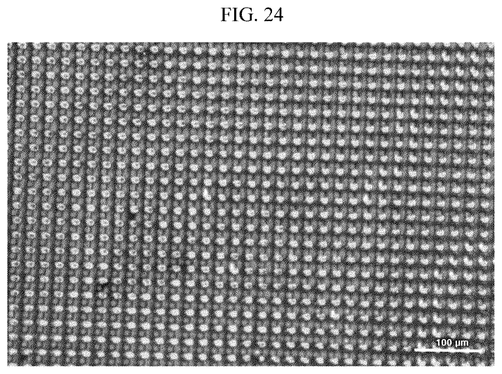

FIG. 21 is a photoluminescence photograph of a green light emitting micro light-emitting diode according to Example 5, FIG. 22 is a photoluminescence photograph of a micro red light-emitting diode according to Example 6, FIG. 23 is a photoluminescence photograph of a blue light emitting micro light-emitting diode according to Example 7, and FIG. 24 is a photoluminescence photograph of a multi-color light emitting micro light-emitting diode according to Example 8. Referring to FIGS. 21 to 24, it may be confirmed that the micro light-emitting diodes according to Examples exhibit excellent green, red, blue, and multi-colored electroluminescence in the plurality of micro-scale patterns.

### Evaluation V

The micro light-emitting diodes according to Examples are evaluated with respect to light-emitting characteristics.

The results are shown in Table 6.

TABLE 6

| | Maximum | Full width |
|---|---|---|
| | emission | at half |
| | wavelength | maximum |
| | (nm) | (FWHM, nm) |
| Example 5 | 512 | 19.87 |
| Example 6 | 680 | 37.31 |
| Example 7 | 478 | 19.16 |

Referring to Table 6, it may be confirmed that the micro light-emitting diodes according to Examples exhibit excellent light-emitting characteristics with narrow full width at half maximum (FWHM) in green, red, and blue wavelength regions, respectively.

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A method of manufacturing a microstructure array, comprising:
preparing a tip array including a plurality of tips, each of the plurality of tips having a truncated pyramidal shape;
applying a perovskite precursor solution on the tip array,
annealing the perovskite precursor solution applied on the tip array to form a plurality of perovskite crystal patterns including perovskite nanocrystals formed from the perovskite precursor solution on the tip array; and
transferring the plurality of perovskite crystal patterns onto a substrate to form a microstructure array including a plurality of microstructures.

2. The method of claim 1, wherein the preparing of the tip array comprises:
preparing a mold having a plurality of recesses, each of the plurality of recesses having a truncated pyramidal shape,
supplying an elastic polymer solution including an elastic polymer precursor and a curing agent in a weight ratio of about 5:1 to about 20:1 to the mold,
curing the elastic polymer solution to cast it into the tip array including the plurality of tips, and
separating the tip array from the mold.

3. The method of claim 2, wherein the elastic polymer precursor comprises a polydimethylsiloxane precursor.

4. The method of claim 2, wherein the preparing of the tip array further comprises performing a Soxhlet extraction.

5. The method of claim 1, wherein a surface roughness of an upper surface of the tip is about 1 nm to about 5 nm.

6. The method of claim 1, wherein a width of an upper surface of the tip is less than about 50 μm.

7. The method of claim 1, further comprising performing oxygen plasma treatment on the surfaces of the plurality of tips, before applying the perovskite precursor solution onto the tip array.

8. The method of claim 7, wherein a contact angle of the surface of the plurality of tips treated with the oxygen plasma is from 0 degrees to about 20 degrees.

9. The method of claim 1, wherein the annealing is performed at a temperature of about 50 to about 200° C.

10. The method of claim 1, wherein an average crystal size of the perovskite nanocrystals in each of the perovskite crystal patterns is less than about 100 nm.

11. The method of claim 1, further comprising forming an electrode or a stack of an electrode and a charge auxiliary layer on the substrate before transferring of the plurality of perovskite crystal patterns onto the substrate,
wherein the perovskite crystal patterns are transferred onto the electrode or the stack of the electrode and the charge auxiliary layer.

12. The method of claim 1, wherein each of the microstructures is configured to emit light in at least one wavelength region among red wavelength region, green wavelength region, and blue wavelength region.

13. A method of manufacturing a micro light-emitting diode, comprising:
forming a first electrode on a substrate,
forming a microstructure array on the first electrode, and
forming a second electrode on the microstructure array,
wherein the forming of the microstructure array comprises
forming a first microstructure array in which a plurality of first microstructures are arranged, each of the plurality of first microstructures including first perovskite nanocrystals emitting light of a first wavelength region,
forming a second microstructure array in which a plurality of second microstructures are arranged, each of the plurality of second microstructures including second perovskite nanocrystals emitting light of a second wavelength region different from the first wavelength region, and
forming a third microstructure array in which a plurality of third microstructures are arranged, each of the plurality of third microstructures including third perovskite nanocrystals emitting light of a third wavelength region different from the first and second wavelength regions,
wherein at least one of the forming of the first, second, and third microstructure arrays is performed according to the method of claim 1.

14. The method of claim 13, wherein the preparing of the tip array comprises preparing a mold having a plurality of recesses with a truncated pyramidal shape,
supplying an elastic polymer solution including an elastic polymer precursor and a curing agent in a weight ratio of about 5:1 to about 20:1 to the mold,
curing the elastic polymer solution to cast it into the tip array including a plurality of tips, each of the plurality of tips having a truncated pyramidal shape, and
separating the tip array from the mold.

15. The method of claim 13, wherein the preparing of the tip array further comprises performing a Soxhlet extraction.

16. The method of claim 13, wherein
a surface roughness of an upper surface of the tip is about 1 nm to about 5 nm, and
an average crystal size of the first, second, and third perovskite nanocrystals is less than or equal to about 100 nm.

17. The method of claim 13, further comprising performing oxygen plasma treatment on the surfaces of the plurality of tips, before applying the perovskite precursor solution onto the tip array.

18. The method of claim 13, wherein the annealing is performed at a temperature of about 50 to about 200° C.

19. A micro light-emitting diode manufactured according to the method of claim 13.

20. A display device comprising a micro light-emitting diode according to claim 19.
